(19) United States
(12) Patent Application Publication
(10) Pub. No.: US 2026/0122832 A1
(43) Pub. Date: Apr. 30, 2026

(54) SUPPORT FRAME

(71) Applicant: FOSITEK CORPORATION, New Taipei City (TW)

(72) Inventors: Kai-Hung LIN, New Taipei City (TW); Kuan-Wei CHEN, New Taipei City (TW)

(73) Assignee: FOSITEK CORPORATION, New Taipei City (TW)

(21) Appl. No.: 19/016,489

(22) Filed: Jan. 10, 2025

(30) Foreign Application Priority Data
Oct. 30, 2024 (TW) 113141604

(51) Int. Cl. H05K 7/18; H05K 7/14

(52) U.S. Cl. CPC H05K 7/183; H05K 7/1489

(57) ABSTRACT

A support frame for a server cabinet includes a first rod member, a second rod member, a third rod member and a connection unit. The first rod member extends in a first direction. The second rod member and the third rod member are respectively disposed on opposite ends of the first rod member that are spaced apart from each other in the first direction. The second rod member is slidable relative to the first rod member in the first direction between a usage position and a storage position. The third rod member is pivotable relative to the first rod member between an unfolded position and a folded position. The connection unit is disposed on the first rod member, the second rod member and the third rod member for being connected to the server cabinet.

### CROSS-REFERENCE TO RELATED APPLICATION

This application claims priority to Taiwanese Invention Patent Application No. 113141604, filed on Oct. 30, 2024, the entire disclosure of which is incorporated by reference herein.

### FIELD

The disclosure relates to a support frame, and more particularly to a support frame for a server cabinet.

### BACKGROUND

A conventional support frame is adapted for being mounted to a cabinet body of a server cabinet and positioning a plurality of slide rail units of the server cabinet, and is in a shape of a long strip. Since the server cabinet has a large size, causing the conventional support frame to have a long length, the conventional support frame is difficult to be transported, and may be easily damaged during transportation.

### SUMMARY

Therefore, an object of the disclosure is to provide a support frame that can alleviate at least one of the drawbacks of the prior art.

According to the disclosure, a support frame for a server cabinet includes a first rod member, a second rod member, a third rod member and a connection unit. The first rod member extends in a first direction. The second rod member and the third rod member are respectively disposed on two opposite ends of the first rod member that are spaced apart from each other in the first direction. The second rod member is slidable relative to the first rod member in the first direction between a usage position and a storage position. The third rod member is pivotable relative to the first rod member between an unfolded position and a folded position. The connection unit is disposed on the first rod member, the second rod member and the third rod member for being connected to the server cabinet.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic perspective view illustrating an embodiment of a support frame according to the disclosure being mounted to a server cabinet.

FIG. 2 is a schematic perspective view of the embodiment, illustrating a second rod member in a usage position and a third rod member in an unfolded position.

FIG. 3 is a fragmentary perspective view of the embodiment, illustrating the second rod member in the usage position and the third rod member in the unfolded position.

FIG. 4 is a fragmentary exploded perspective view of the embodiment.

FIG. 5 is a fragmentary exploded perspective view of the embodiment.

FIG. 6 is a schematic perspective view of the embodiment, illustrating the second rod member in a storage position and the third rod member in the unfolded position.

FIG. 7 is a schematic perspective view of the embodiment, illustrating the second rod member in the storage position and the third rod member in a folded position.

FIG. 8 is a sectional view of FIG. 7.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

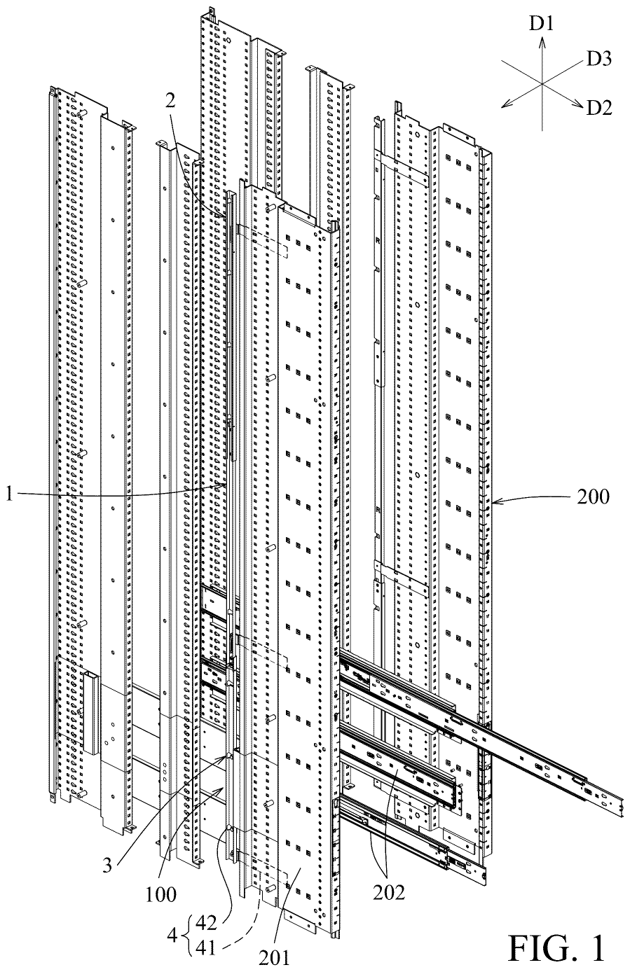

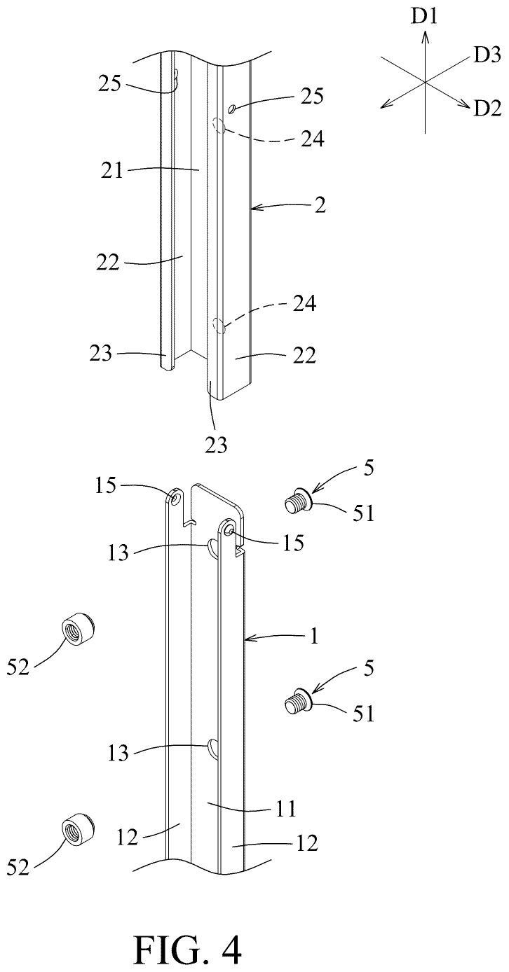

Referring to FIGS. 1 to 4, an embodiment of a support frame 100 according to the disclosure is adapted to be mounted to a server cabinet 200. The server cabinet 200 includes a cabinet body 201 and a plurality of slide rail units 202. The support frame 100 includes a first rod member 1, a second rod member 2, a third rod member 3 and a connection unit 4.

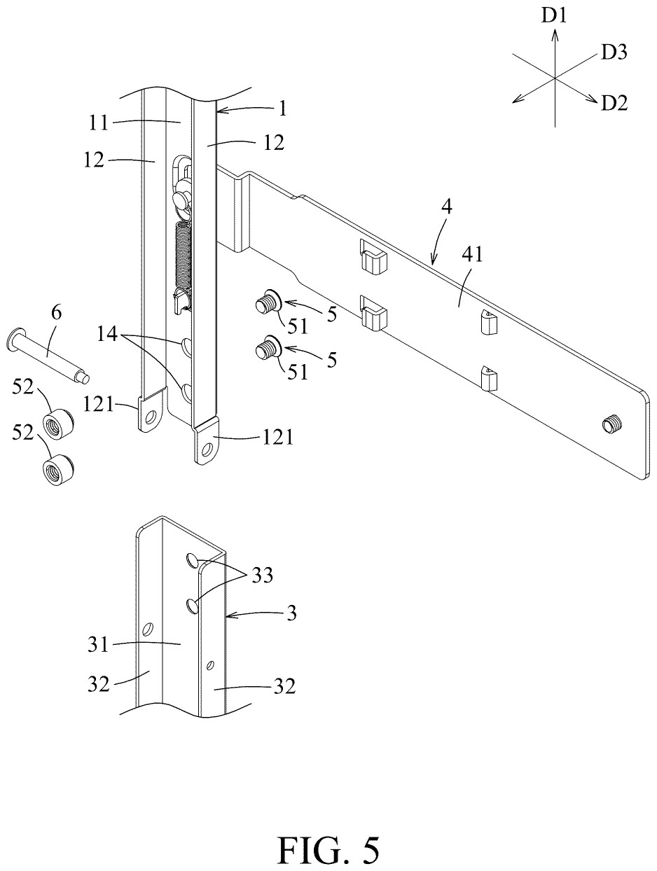

The first rod member 1 extends in a first direction (D1), and has a first main wall 11 that has two opposite sides spaced apart from each other in a second direction (D2), two first side walls 12 that extend respectively from the opposite sides of the first main wall 11 in a third direction (D3), a first secure portion 13, a second secure portion 14 (see FIG. 5), and two first position portions 15. The first direction (D1), the second direction (D2) and the third direction (D3) are perpendicular to each other. It should be noted that in this embodiment, the first rod member 1 has a plurality of first secure portions 13 and a plurality of second secure portions 14, but is not limited to such. In one embodiment, the first secure portions 13 and the second secure portions 14 are through holes; in the first direction (D1), the first secure portions 13 are formed in an upper end of the first main wall 11, and the second secure portions 14 are formed in a bottom end of the first main wall 11. In this embodiment, the first position portions 15 are bumps that protrude outwards and that are respectively formed on upper ends of the first side walls 12 in the first direction (D1).

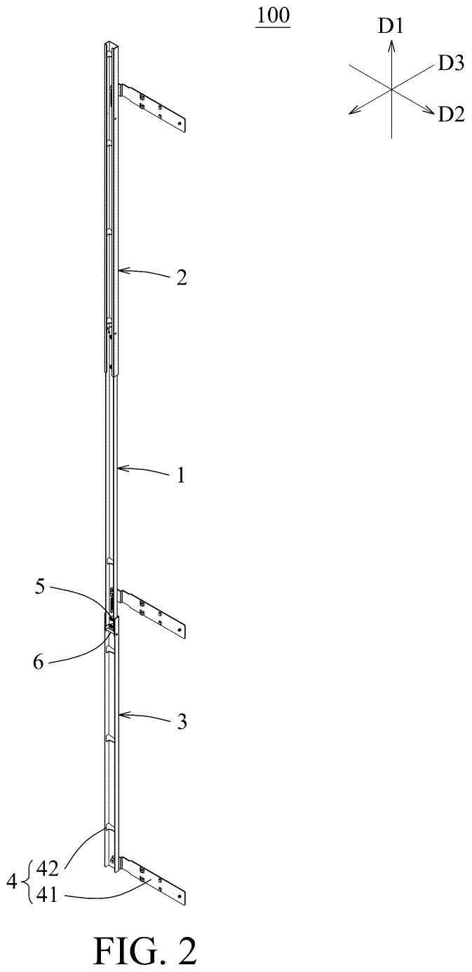

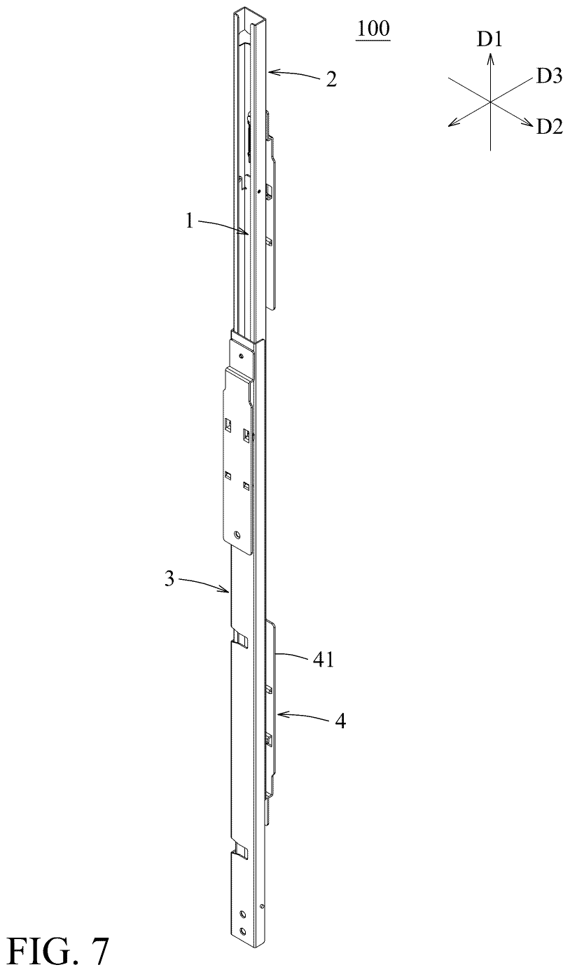

The second rod member 2 and the third rod member 3 are respectively disposed on two opposite ends of the first rod member 1 that are spaced apart from each other in the first direction (D1); in this embodiment, the second rod member 2 is disposed on an upper end of the first rod member 1, and the third rod member 3 is disposed on a bottom end of the first rod member 1, but the disclosure is not limited to such. The second rod member 2 is slidable relative to the first rod member 1 in the first direction (D1) between an usage position (see FIG. 2) and a storage position (see FIG. 7), and has a second main wall 21 that corresponds to the first main wall 11, two second side walls 22 that are respectively connected to two opposite ends of the second main wall 21 in the second direction (D2) and that are respectively located at two opposite sides of the first side walls 12 in the second direction (D2), two limit walls 23 that are respectively connected to the second side walls 22 and that are respectively adjacent to the first side walls 12, a slide secure portion or third secure portion 24 and two second position portions 25. Specifically, in this embodiment, the second rod member 2 has a plurality of third secure portions 24, but is not limited to such; the third secure portions 24 respectively correspond in position to the first secure portions 13, and the second position portions 25 are respectively correspond in position to the first position portions 15. Each of the limit walls 23 is spaced apart from the first main wall 11 in the third direction (D3) by the respective one of the first side walls 12. The third secure portions 24 are through holes and are formed in the second main wall 21. The support frame 100 further includes a plurality of fastener units 5, each of which includes a screw 51 and a nut 52. Each of the third secure portions 24 and the respective one of the first secure portions 13 are configured to be secured to each other through one of the fastener units 5. The second position portions 25 are through holes and are respectively formed in the second side walls 22. Each of the second position portions 25 and the respective one of the first position portions 15 are configured to be complementary and engaged with each other.

Referring to FIGS. 1 to 3 and 5, the third rod member 3 is pivotable relative to the first rod member 1 between an unfolded position (see FIG. 2) and a folded position (see FIG. 7), and has a third main wall 31 that corresponds to the first main wall 11, two third side walls 32 that are connected to the third main wall 31 and that are respectively located at the opposite sides of the first side walls 12 in the second direction (D2), and a pivot secure portion or fourth secure portion 33. In this embodiment, the third rod member 3 has a plurality of fourth secure portions 33, which respectively correspond in position to the second secure portions 14. Specifically, in this embodiment, the first side walls 12 of the first rod member 1 have extension wall portions 121 that are respectively located at bottom ends thereof, and a distance between the extension wall portions 121 in the second direction (D2) is substantially equal to a distance between the second side walls 22 in the second direction (D2). The third side walls 32 are located at two opposite sides of the extension wall portions 121 in the second direction (D2), and are pivotally connected to the extension wall portions 121 through a pivot member 6 that extends through the extension wall portions 121 and the third side walls 32 in the second direction (D2). The fourth secure portions 33 are through holes and are formed in the third main wall 31. Each of the fourth secure portions 33 and the respective one of the second secure portions 14 are configured to be secured to each other through one of the fastener units 5.

The connection unit 4 is disposed on the first rod member 1, the second rod member 2 and the third rod member 3 for being connected to the server cabinet 200, and includes a plurality of metal plates 41 that are disposed on the first rod member 1, the second rod member 2 and the third rod member 3, and a plurality of position holes 42 that are formed in the first rod member 1, the second rod member 2 and the third rod member 3. The metal plates 41 are configured to be mounted to the cabinet body 201 of the server cabinet 200, and the position holes 42 are configured to position the slide rail units 202 of the server cabinet 200. In this embodiment, the metal plates 41 are rotatably disposed on the first rod member 1, the second rod member 2 and the third rod member 3, such that the metal plates 41 may be folded on the first rod member 1, the second rod member 2 and the third rod member 3 for storage or transportation (see FIG. 7) before the support frame 100 is mounted to the server cabinet 200, but are not limited thereto.

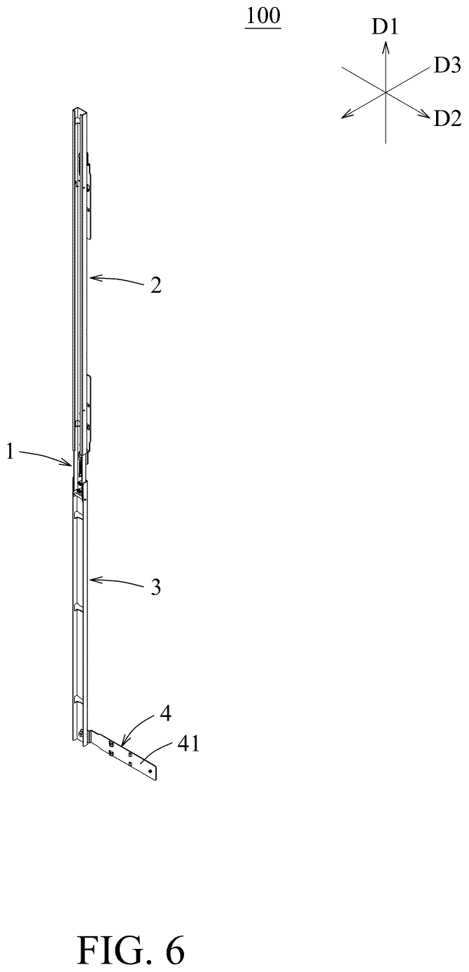

When the second rod member 2 is in the usage position, where each of the second position portions 25 and the respective one of the first position portions 15 are engaged with each other to provide an indication to a user, and when the third rod member 3 is in the unfolded position, the second main wall 21 and the third main wall 31 are coplanar; specifically, the second main wall 21 and the third main wall 31 abut against a same surface of the first main wall 11 in the third direction (D3). In addition, each of the third secure portions 24 and the respective one of the first secure portions 13 are secured to each other through one of the fastener units 5, and each of the fourth secure portions 33 and the respective one of the second secure portions 14 are secured to each other through one of the fastener units 5, thereby having the second rod member 2 and the third rod member 3 stayed in the usage position and the unfolded position, respectively. At the same time, the support frame 100 may be mounted to the cabinet body 201 and position the slide rail units 202 through the connection unit 4. In this embodiment, when the support frame 100 is to be stored or transported, the fastener units 5 are first unscrewed and remove from the third secure portions 24, the first secure portions 13, the fourth secure portions 33 and the second secure portions 14, then the second rod member 2 is slid from the usage position to the storage position (as shown in FIG. 6), and the third rod member 3 is pivoted from the unfolded position to the folded position (as shown in FIG. 7).

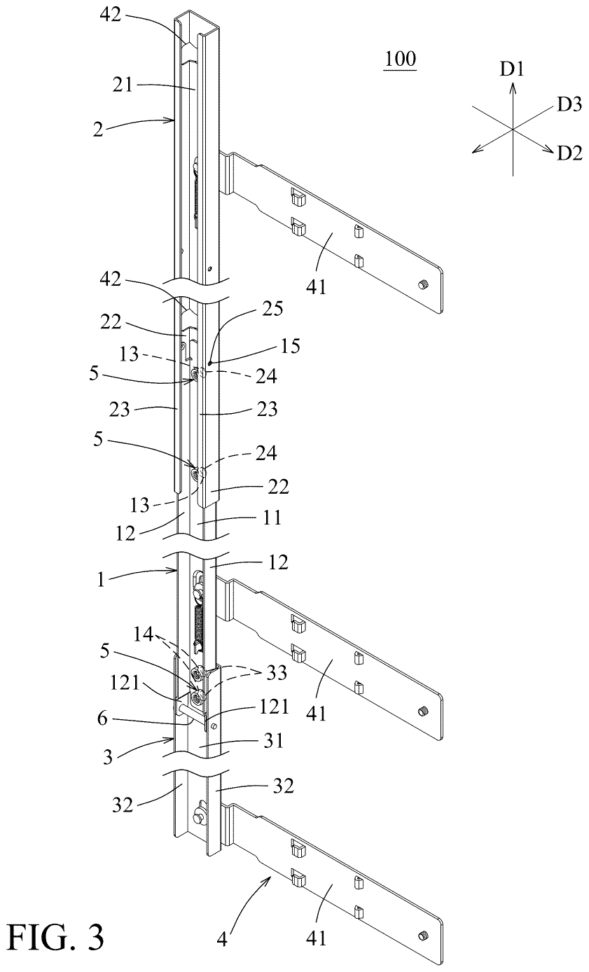

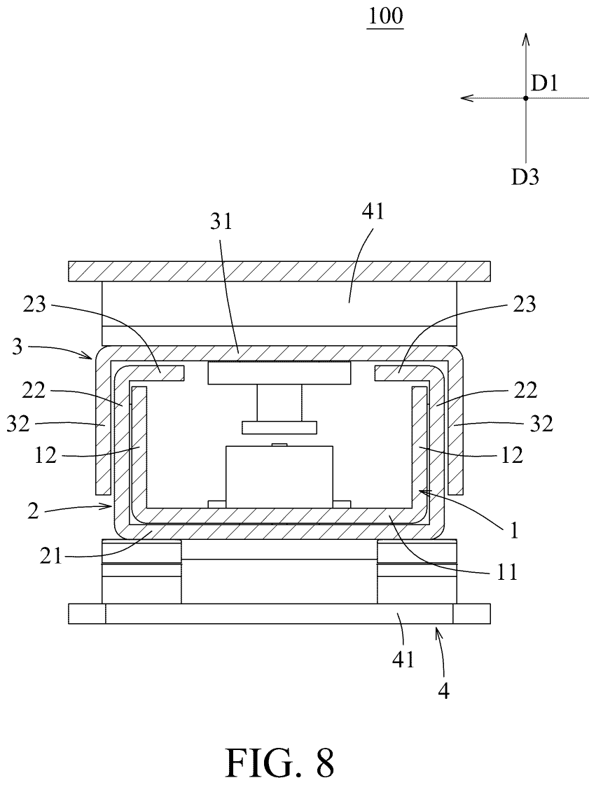

Referring to FIG. 3, since the distance between the extension wall portions 121 in the second direction (D2) is substantially equal to the distance between the second side walls 22 in the second direction (D2), and since the third side walls 32 are located at the opposite sides of the extension wall portions 121 in the second direction (D2) and are pivotally connected to the extension wall portions 121, when the second rod member 2 is in the storage position and when the third rod member 3 is in the folded position, the third side walls 32 of the third rod member 3 are respectively adjacent to and partially cover the second side walls 22 of the second rod member 2 in the second direction (D2) while the third side walls 32 do not contact the second side walls 22 (see FIGS. 7 and 8), so that interference does not occur therebetween. In addition, the second main wall 21 of the second rod member 2 and the third main wall 31 of the third rod member 3 are respectively located at two opposite sides of the first rod member 1 in the third direction (D3); specifically, the second main wall 21 and the third main wall 31 are spaced apart from each other by the first rod member 1 in the third direction (D3), so that the second main wall 21, the second side walls 22 and the limit walls 23 of the second rod member 2 and the third main wall 31 and the third side walls 32 of the third rod member 3 cooperatively cover at least a portion of the first rod member 1, thereby protecting the first rod member 1 that has a relatively weak structural strength.

To sum up, since the second rod member 2 is slidable and the third rod member 3 is pivotable to change a length of the support frame 100, the support frame 100 is easier to be transported and may not be easily damaged during transportation; furthermore, such structure allows the second main wall 21 and the third main wall 31 to be coplanar when the support frame 100 is used, and the second rod member 2 and the third rod member 3 to cooperatively cover at least a portion of the first rod member 1 when the support frame 100 is to be transported or stored, thereby protecting the first rod member 1 that has a relatively weak structural strength.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A support frame for a server cabinet, comprising:
a first rod member extending in a first direction;
a second rod member and a third rod member respectively disposed on two opposite ends of said first rod member that are spaced apart from each other in the first direction, said second rod member being slidable relative to said first rod member in the first direction between a usage position and a storage position, said third rod member being pivotable relative to said first rod member between an unfolded position and a folded position; and
a connection unit disposed on said first rod member, said second rod member and said third rod member for being connected to the server cabinet.

2. The support frame as claimed in claim 1, wherein said first rod member has a first main wall that has two opposite sides spaced apart from each other in a second direction, and two first side walls that extend respectively from said opposite sides of said first main wall in a third direction, the first direction, the second direction and the third direction being perpendicular to each other, said second rod member having a second main wall, and two second side walls that are connected to said second main wall and that are respectively located at two opposite sides of said first side walls in the second direction, said third rod member having a third main wall, and two third side walls that are connected to said third main wall and that are respectively located at the opposite sides of said first side walls in the second direction.

3. The support frame as claimed in claim 2, wherein when said second rod member is in the storage position and when said third rod member is in the folded position, said second main wall and said second side walls of said second rod member and said third main wall and said third side walls of said third rod member cooperatively cover at least a portion of said first rod member.

4. The support frame as claimed in claim 2, wherein said first side walls of said first rod member respectively have extension wall portions, a distance between said extension wall portions in the second direction being equal to a distance between said second side walls in the second direction, said third side walls being pivotally connected to said extension wall portions through a pivot member, and being located at two opposite sides of said extension wall portions in the second direction.

5. The support frame as claimed in claim 4, wherein said pivot member extends through said extension wall portions and said third side walls in the second direction.

6. The support frame as claimed in claim 2, wherein said second rod member further has two limit walls that are respectively connected to said second side walls and that are respectively adjacent to said first side walls, each of said limit walls being spaced apart from said first main wall by the respective one of said first side walls in the third direction.

7. The support frame as claimed in claim 2, wherein when said second rod member is in the usage position and when the third rod member is in the unfolded position, said second main wall and said third main wall are coplanar.

8. The support frame as claimed in claim 1, wherein
said first rod member has a first secure portion and a second secure portion, said second rod member having a slide secure portion that corresponds in position to said first secure portion, said third rod member having a pivot secure portion that corresponds in positon to said second secure portion,
when said second rod member is in the usage position, said first secure portion and said slide secure portion are able to be secured to each other, and
when said third rod member is in the unfolded position, said second secure portion and said pivot secure portion are able to be secured to each other.

9. The support frame as claimed in claim 8, further comprising a plurality of fastener units that are configured to secure said first secure portion to said slide secure portion, and to secure said second secure portion to said pivot secure portion.

10. The support frame as claimed in claim 1, wherein
said first rod member has a first position portion, and said second rod member has a second position portion, and
when said second rod member is in the usage position, said first position portion and said second position portion are complementary and are engaged with each other.

11. The support frame as claimed in claim 1, wherein said connection unit includes a plurality of metal plates that are disposed on said first rod member, said second rod member and said third rod member, and a plurality of position holes that are formed in said first rod member, said second rod member and said third rod member, said plurality of metal plates being configured to be mounted to a cabinet body of the server cabinet, said plurality of position holes being configured to position a plurality of slide rail units of the server cabinet.
